(19) United States
(12) Patent Application Publication
(10) Pub. No.: US 2026/0190788 A1
(43) Pub. Date: Jul. 2, 2026

(54) Display Device

(71) Applicant: LG Display Co., Ltd., Seoul (KR)

(72) Inventors: Hyesun Son, Seoul (KR); Hyesun Song, Seoul (KR); SangHoon Oh, Seoul (KR)

(21) Appl. No.: 19/432,721

(22) Filed: Dec. 24, 2025

(30) Foreign Application Priority Data
Dec. 30, 2024 (KR) 10-2024-0201383

(51) Int. Cl. H10K 59/80

(52) U.S. Cl. CPC H10K 59/873; H10K 59/8792

(57) ABSTRACT

A display device presented herein includes a non-bending area, a first bending area extending from a side portion of the non-bending area, a second bending area extending from a corner of the non-bending area and positioned between two first bending areas, a cover glass including a front portion corresponding to the non-bending area and a curved portion corresponding to the bending area and bent to have a curvature, a display panel disposed under the cover glass and including a first area corresponding to the non-bending area and a second area corresponding to the bending area, a metal plate supporting the display panel below the display panel, and an adhesive layer adhering the cover glass, the display panel, and the metal plate. The adhesive layer covers a top surface, a bottom surface, and a side portion of the display panel and contacts the cover glass.

### CROSS-REFERENCE TO RELATED APPLICATION

The present application claims priority to Republic of Korea Patent Application No. 10-2024-0201383 filed on Dec. 30, 2024, which is incorporated herein by reference in its entirety.

### BACKGROUND

### Field

The present disclosure relates to a display device, and more particularly, to a display device with improved durability and reliability in a bending area.

### Discussion of Related Art

In recent years, as society has entered a full-fledged information era, the field of display that processes and displays a large amount of information has rapidly developed. Display devices used for a monitor of a computer, a TV, or a mobile phone include an organic light emitting display (OLED) that emits light by itself, and a liquid crystal display (LCD) that requires a separate light source.

Display devices have been applied in a variety of applications, including computer monitors and TVs as well as personal portable devices, and research is being conducted on display devices that have a large display area and have a reduced volume and weight.

Recently, flexible display devices manufactured to display images even when bent or folded like paper are attracting attention as next-generation display devices. The flexible display device may be classified into an unbreakable display device having high durability by utilizing a plastic thin film transistor substrate other than glass, a bendable display device which may be bent without breaking, a rollable display device which may be rolled, and a foldable display device which may be folded. Such a flexible display device has advantages in space utilization, interior, and design, and may have various application fields.

In particular, a cover glass is generally formed on the front surface of the display device, and the user may recognize the display screen through the cover glass. In this case, the cover glass generally has a flat shape, but in recent years, the demand for a curved display device in which the side portion and the edge of the cover glass have a curved shape has increased. In the curved display device, a screen may be recognized through a cover glass even on some side surfaces of the display device, thereby obtaining an effect of expanding a substantial screen size.

In a curved display device, components such as a display panel, a support substrate, and other films should have a flat shape at a center portion corresponding to a cover glass shape and maintain a bent shape at an edge including an edge and a side portion. At this time, stress was generated on the components bent at the corners and sides, and the adhesive layer to which each component was attached, causing problems in durability, such as peeling of each component, occurrence of wrinkles and bubbles on the corners, or peeling.

### SUMMARY

An object to be achieved by the present disclosure is to provide a display device having a four-sided bending structure in which all edges including edges are bent.

Another object to be achieved by the present disclosure is to provide a display device which effectively relieves stress applied to an edge of the display device to minimize or at least reduce peeling between an adhesive layer and an adherend.

Still another object to be achieved by the present disclosure is to provide a display device in which damage is suppressed in a corner portion to which a lot of stress is applied.

Still another object to be achieved by the present disclosure is to provide a display device capable of solving wrinkles and air bubbles generated at a corner of the display device.

Objects of the present disclosure are not limited to the above-mentioned objects, and other objects, which are not mentioned above, can be clearly understood by those skilled in the art from the following descriptions.

A display device according to one or more embodiments of the present disclosure includes a non-bending area and a first bending area extending from a side portion of the non-bending area and a second bending area extending from a corner of the non-bending area and positioned between two first bending areas, a cover glass including a front portion corresponding to the non-bending area and a curved portion corresponding to the bending area and bent to have a curvature; a display panel disposed under the cover glass and including a first area corresponding to the non-bending area and a second area corresponding to the bending area; a metal plate supporting the display panel below the display panel; and an adhesive layer adhering the cover glass, the display panel, and the metal plate, and the adhesive layer covers a top surface, a bottom surface, and a side portion of the display panel and contacts the cover glass.

Other detailed matters of the embodiments are included in the detailed description and the drawings.

According to the present disclosure, in the display device, an internal component of a cover glass having a curved portion is attached and protected by using an adhesive layer made of the same material and the same properties, thereby improving the durability and reliability of the display device.

According to one or more embodiments of the present disclosure, in the display device, the adhesiveness of the cover glass in the bent portion is improved while maintaining the convenience in the process, so that the peeling off or the occurrence of wrinkles and bubbles can be suppressed by the repulsive force which is to be restored to the shape before the component is bent.

According to one or more embodiments the present disclosure, in the display device, it is possible to solve the problem of generating air bubbles due to a step difference caused by a black matrix disposed inside a cover glass having a curved portion.

The effects according to embodiments of the present disclosure are not limited to the contents exemplified above, and more various effects are included in the present disclosure.

### BRIEF DESCRIPTION OF THE DRAWINGS

The above and other embodiments, features and other advantages of the present disclosure will be more clearly understood from the following detailed description taken in conjunction with the accompanying drawings, in which:

FIG. 1 is a schematic perspective view of a display device according to one or more embodiments of the present disclosure.

FIG. 2 is a schematic cross-sectional view of a display device according to one or more embodiments of the present disclosure.

FIGS. 3A to 3D are schematic cross-sectional views for explaining a method of manufacturing a display device according to one or more embodiments of the present disclosure.

FIG. 4 is a schematic cross-sectional view of a display device according to one or more other embodiments of the present disclosure.

FIGS. 5A to 5F are schematic cross-sectional views for explaining a method of manufacturing a display device according to one or more other embodiments of the present disclosure.

FIG. 6A is a schematic cross-sectional view of a display device according to a comparative example.

FIG. 6B is an image obtained by photographing area A in FIG. 6A in a plane direction.

FIG. 7 is a result showing durability evaluation for Embodiments 1 to 3 and Comparative Examples 1 to 3.

### DETAILED DESCRIPTION

Advantages and characteristics of the present disclosure and a method of achieving the advantages and characteristics will be clear by referring to embodiments described below in detail together with the accompanying drawings. However, the present disclosure is not limited to the embodiments disclosed herein but will be implemented in various forms. The embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the embodiments of the present disclosure are merely examples, and the present disclosure is not limited thereto. Further, in the following description of the present disclosure, a detailed explanation of known related technologies may be omitted to avoid unnecessarily obscuring the subject matter of the present disclosure. The terms such as “including,” “having,” “comprising,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, embodiments of the present disclosure will be described in detail with reference to accompanying drawings.

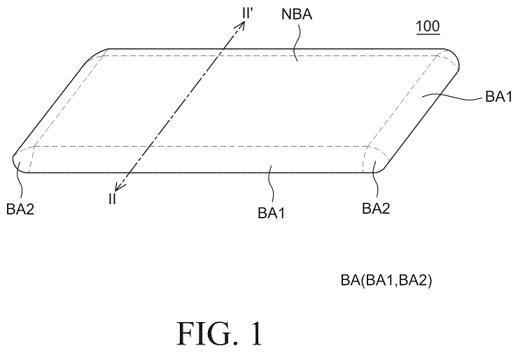

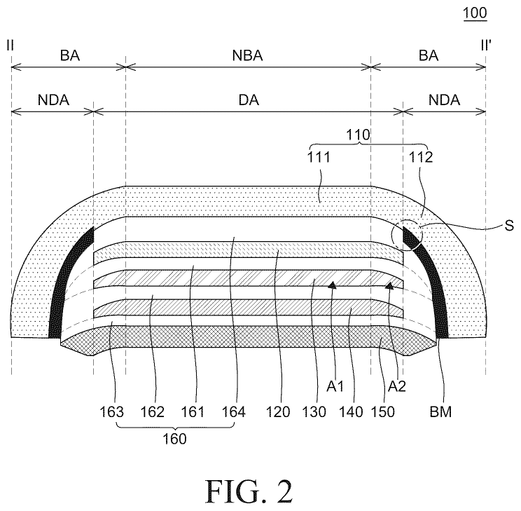

FIG. 1 is a schematic perspective view of a display device according to one or more embodiments of the present disclosure. FIG. 2 is a schematic cross-sectional view of a display device according to one or more embodiments of the present disclosure.

Referring to FIGS. 1 and 2, the display device 100 includes a non-bending area NBA and a bending area BA.

The non-bending area NBA is an area in which the display device 100 is maintained in a flat state. The entire non-bending area NBA may be configured as a display area.

The bending area BA is an area where the display device 100 is bent. The bending area BA is located at an edge of the display device 100 and may be an area extending from a side portion and an edge of the non-bending area NBA. In this case, the bending area BA may be entirely or partially configured as a display area, or a part of the bending area BA may be configured as a non-display area, but is not limited thereto.

The bending area BA includes a first bending area BA1 extending from a side portion of the non-bending area NBA and a second bending area BA2 extending from a corner of the non-bending area NBA.

First, the first bending area BA1 extends from the non-bending area NBA and is disposed on the side portion of the non-bending area NBA. As illustrated in FIG. 1, when the non-bending area NBA has a rectangular shape, the first bending area BA1 may be an area which extends from four side surfaces of the non-bending area NBA and is bent with a specific radius of curvature. For example, the first bending area BA1 may be bent with a composite curvature of about 5 mm to 8 mm.

The second bending area BA2 is an area extending from the corner of the non-bending area NBA. As illustrated in FIG. 1, when the non-bending area NBA has a rectangular shape, the second bending area BA2 may be an area which extends from four corners of the non-bending area NBA and is bent with a specific radius of curvature. For example, the second bending area BA2 may be bent with a composite curvature of about 5 mm to 8 mm.

The first bending area BA1 and the second bending area BA2 are disposed to surround the non-bending area NBA and may be alternately disposed. That is, the second bending area BA2 may be disposed between the two first bending areas BA1, and the first bending area BA1 may be disposed between the two second bending areas BA2.

Meanwhile, the display device 100 according to one or more embodiments of the present disclosure may include a display area DA and a non-display area NDA. The display area DA is an area in which a plurality of pixels are disposed and an image is substantially displayed. The non-display area NDA may be positioned to surround the display area DA. The non-display area NDA is an area where an image is not substantially displayed and various wiring lines, driving ICs, printed circuit boards, and the like for driving pixels and driving circuits disposed in the display area DA are disposed. For example, in the non-display area NDA, various ICs such as a gate driver IC and a data driver IC, VSS lines, and the like may be disposed. As described above, the display area DA is disposed in the non-bending area NBA and extends from the non-bending area NBA to be disposed in at least a part of the bending area BA.

Referring to FIGS. 1 and 2, a display device 100 according to one or more embodiments of the present disclosure includes a cover glass 110, a polarizing film 120, a display panel 130, a back plate 140, and a metal plate 150.

When the direction in the drawing is defined with reference to FIG. 2, under the premise that the display surface of the display device 100 faces forward, the polarizing film 120 and the cover glass 110 are positioned on the display panel 130 in the direction of the display surface of the display device 100, and the back plate 140 and the metal plate 150 are positioned below the display panel 130 in the lower direction of the display device 100. Each component is attached through an adhesive layer 160.

The cover glass 110 is disposed at the top of the display device 100 to protect the components of the display device 100 from external impact and prevent damage such as scratches.

The cover glass 110 may be bent in a curved shape having a preset radius of curvature from all edges. Accordingly, the edge of the cover glass 110 may have a structure that is bent as a whole. Accordingly, the cover glass 110 has a four-sided bending structure that is bent as a whole to improve the aesthetics of the display device 100 and reduce the bezel width in each of the long-side direction and the short-side direction of the display device 100.

Specifically, referring to FIG. 2, the cover glass 110 includes a front portion 111 corresponding to the non-bending area NBA and a curved portion 112 corresponding to the bending area BA. The front portion 111 has a planar shape corresponding to the non-bending area NBA. When the non-bending area NBA has a rectangular shape, the front portion 111 may also have a rectangular shape.

The curved portion 112 is disposed at the edge of the front portion 111 and corresponds to the bending area BA. The curved portion 112 extends from the front portion 111 and is bent, and may have a preset radius of curvature. The curved portion 112 may include a first curved portion positioned at a side portion of the front portion 111 and corresponding to the first bending area BA1, and a second curved portion positioned at a corner and corresponding to the second bending area BA2. The first curved portion extends and is bent from the four side portions of the front portion 111. The four first curved portions located on the four side portions of the front portion 111 may have the same radius of curvature or may have some different radius of curvature. The second curved portion extends from the corner of the front portion 111 and is bent. The second curved portion is located at the corner of the cover glass 110 to connect the two first curved portions. The second curved portion may be a curved surface having at least two curvatures.

A black matrix BM may be formed on a bottom surface of the cover glass corresponding to the non-display area NDA. Referring to FIG. 2, the black matrix BM may be disposed inside the curved portion 112 of the cover glass. The black matrix BM includes a light-absorbing material, for example, a light-absorbing metal, carbon black, black resin, or the like. Accordingly, components such as wiring disposed in the non-display area NDA are not visually recognized to the outside. In addition, the black matrix BM may prevent light leakage from the side surface of the display device.

The polarizing film 120 is disposed under the cover glass 110. The polarizing film 120 polarizes light emitted from the display panel 130 at a polarization angle. The polarizing film 120 emits light polarized at a polarization angle to the outside. The polarizing film 120 may include a function of blocking reflection of light excluding light polarized at a polarization angle among external light. In the meantime, even though in FIG. 2, it is illustrated that the display device 100 includes a polarizing film 120, the polarizing film 120 may be omitted depending on the design.

The display panel 130 may be disposed below the polarizing film 120. The display panel 130 is a panel in which an image is implemented, and a substrate, a display element for implementing an image, and a circuit unit for driving the display element may be disposed. For example, when the display device 100 is an organic light emitting display device, the display element may include an organic light emitting element. Hereinafter, for convenience of description, it is assumed that the display device 100 according to one or more embodiments of the present disclosure is a display device including an organic light emitting element, but it is not limited thereto.

The substrate supports various elements constituting the display panel 130. The flexible substrate may be formed of an insulating material having a very thin thickness to implement the flexibility. The substrate may be made of glass or resin. In addition, the substrate may include plastic such as polymer or polyimide (PI) or may be made of a material having flexibility. For example, the flexible substrate may be an insulating plastic substrate selected from polyimide, polyethersulfone, polyethylene terephthalate, and polycarbonate, but is not limited thereto.

The circuit unit may include various thin film transistors, capacitors, wirings, and driving ICs for driving the display element. For example, the circuit unit may include various configurations such as a driving thin film transistor, a switching thin film transistor, a storage capacitor, a gate line, a data line, a gate driver IC, and a data driver IC, but is not limited thereto.

The display element may be an organic light emitting element. The organic light emitting element may include an anode, a cathode, and an organic light emitting layer disposed therebetween. In the organic light emitting device, holes injected from the anode and electrons injected from the cathode are combined in the organic emission layer to emit light. An image may be displayed using the light emitted as described above.

Meanwhile, referring to FIG. 2, the display panel 130 may define a first area A1 corresponding to the non-bending area NBA and a second area A2 corresponding to the bending area BA.

Specifically, the first area A1 may be a flat area corresponding to the non-bending area NBA. When the non-bending area NBA has a rectangular shape, the first area A1 may also have a rectangular shape. Further, the first area A1 may include a display area DA in which an image is displayed. In the first area A1, a plurality of sub-pixels constituting a plurality of pixels and a circuit for driving the plurality of sub-pixels may be disposed.

Since the second area A2 corresponds to the bending area BA, the second area A2 is an area which is disposed at the edge of the first area A1 and surrounds the first area A1. The second area A2 may be located at a side portion of the first area A1 to correspond to the first bending area BA1, and at the same time, may be located at a corner of the first area A1 to correspond to the second bending area BA2. The second area A2 extends from the first area A1 to be bent from the first area A1 and may have a preset radius of curvature.

The second area A2 may be disposed to overlap the curved portion 112 of the cover glass. At least a part of the second area A2 may include a display area DA in which an image is displayed. In addition, the second area A2 may include not only the display area DA, but also the non-display area NDA. Since the second area A2 including the display area DA is disposed so as to correspond to the bending area BA, a screen may be recognized not only by the front portion 111 of the cover glass, but also by the curved portion 112. Accordingly, a screen may be recognized through the cover glass 110 even on some side surfaces of the display device 100 so that the size of the actual screen may be expanded.

Meanwhile, although not shown in FIG. 2, a touch panel constituting a touch sensor may be selectively disposed between the display panel 130 and the cover glass 110, if necessary.

A back plate 140 for supporting the display panel 130 may be included under the display panel 130. Since the back plate 140 is an upper plate of the two plates disposed below the display panel 130, the back plate 140 may be referred to as a top plate. The back plate 140 may be, for example, a metal material such as stainless steel (SUS) or Invar, or may be formed of plastic such as polymethylmetacrylate (PMMA), polycarbonate (PC), polyvinylalcohol (acrylonitrile-styrene (PVA), ABS), acrylonitrile-butadiene-styrene polyethylene terephthalate (PET), silicone, or polyurethane (PU), but is not limited thereto.

The back plate 140 may include a first back plate corresponding to the non-bending area NBA and a second back plate corresponding to the bending area BA.

The first back plate may be a flat area corresponding to the non-bending area NBA. When the non-bending area NBA has a rectangular shape, the first back plate may also have a rectangular shape. The second back plate may be disposed at a position corresponding to the bending area BA. The second back plate is disposed at the edge of the first back plate and surrounds the first back plate. The second back plate may be located on a side portion of the first back plate and may correspond to the first bending area BA1, and at the same time, may be located at a corner of the first back plate and may correspond to the second bending area BA2. The second back plate may have a preset radius of curvature in the bending area BA corresponding to the display panel 130. The first back plate and the second back plate may be integrally formed. For example, the first back plate and the second back plate may be formed of the same material and formed as one body. However, the present disclosure is not limited thereto, and the first back plate and the second back plate may be formed separately from each other and then connected to each other.

A metal plate 150 for supporting the display panel 130 is disposed below the back plate 140. At this time, the metal plate 150 supports the flexible substrate constituting the display panel 130 so as not to sag and protects components disposed on the flexible substrate from external moisture, heat, impact, and the like.

Since the metal plate 150 is a lower plate of the two plates disposed below the display panel 130, it may be referred to as a bottom plate. The metal plate 150 may be made of a material such as stainless steel (SUS) and amorphous metal which are rigid to maintain the shape of the display panel 130, but is not limited thereto.

Meanwhile, the metal plate 150 may include an opening pattern or an uneven pattern disposed in the bending area BA. Since the metal plate 150 is made of a metal material and has rigidity, a pattern may be formed in the bending area BA to allow the metal plate 150 to be easily bent.

The metal plate 150 may include a first metal plate corresponding to the non-bending area NBA and a second metal plate corresponding to the bending area BA.

The first metal plate may be a flat area corresponding to the non-bending area NBA. When the non-bending area NBA has a rectangular shape, the first metal plate may also have a rectangular shape. The second metal plate may be disposed at a position corresponding to the bending area BA. The second metal plate is disposed at the edge of the first metal plate to surround the first metal plate. The second metal plate may be located on a side portion of the first metal plate and may correspond to the first bending area BA1, and at the same time, may be located at a corner of the first metal plate and may correspond to the second bending area BA2. The second metal plate may have a preset radius of curvature in the bending area BA corresponding to the display panel. The first metal plate and the second metal plate may be integrally formed. For example, the first metal plate and the second metal plate may be formed of the same material and formed as one body. However, the present disclosure is not limited thereto, and the first metal plate and the second metal plate may be formed separately from each other and then connected to each other.

Meanwhile, the metal plate 150 may have a width greater than those of the display panel 130 and the back plate 140 located thereabove. Referring to FIG. 2, the metal plate 150 may have a width greater than that of the display panel 130 and the back plate 140 so as to be more adjacent to the cover glass 110 in the bending area BA. Accordingly, the metal plate 150 may extend to overlap the non-display area NDA. Further, the metal plate 150 may be disposed to be in contact with the inner surface of the curved portion 112 of the cover glass 110. Accordingly, the cover glass 110 and the metal plate 150 may be surrounded to accommodate the display panel 130 and the back plate 140.

The adhesive layer 160 is a component for adhering elements constituting the display device 100 to each other. Referring to FIG. 2, the adhesive layer 160 fills an inner space formed by the cover glass 110 and the metal plate 150 and attaches the cover glass 110, the polarizing film 120, the display panel 130, the back plate 140, and the metal plate 150.

The adhesive layer 160 includes a first adhesive layer 161 disposed on the top surface of the display panel 130 and disposed between the display panel 130 and the polarizing film 120, a second adhesive layer 162 disposed on the bottom surface of the display panel 130 and disposed between the display panel 130 and the back plate 140, a third adhesive layer 163 disposed between the back plate 140 and the metal plate 150, and a fourth adhesive layer 164 disposed between the cover glass 110 and the polarizing film 120. In the meantime, even though in FIG. 2, it is illustrated that the adhesive layer 160 includes a first adhesive layer 161, a second adhesive layer 162, a third adhesive layer 163, and a fourth adhesive layer 164, some adhesive layers may be omitted depending on whether components are used or omitted. For example, when the polarizing film 120 is excluded, the fourth adhesive layer 164 may be omitted, and the first adhesive layer 161 may be disposed between the display panel 130 and the cover glass 110. In this case, the thickness of the first adhesive layer 161 may be implemented as the thickness of the fourth adhesive layer 164. Similarly, when the back plate 140 is excluded, the third adhesive layer 163 may be omitted, and the second adhesive layer 162 may be disposed between the display panel 130 and the metal plate 150. In this case, the thickness of the second adhesive layer 162 may be implemented as the thickness of the third adhesive layer 163.

The first adhesive layer 161 is disposed between the display panel 130 and the polarizing film 120 to attach the display panel 130 and the polarizing film 120. The first adhesive layer 161 is disposed to cover both the upper surface and the side portion of the display panel 130. Therefore, the first adhesive layer 161 may protect and fix the side portion of the display panel 130. In this case, the first adhesive layer 161 may be in contact with the curved portion 112 of the cover glass 110 in the bending area BA or with the black matrix BM disposed inside the curved portion 112. Further, the first adhesive layer 161 may be in contact with the second adhesive layer 162 located below the first adhesive layer 161 and the fourth adhesive layer 164 located on the first adhesive layer 161 in the bending area BA. In this case, the thickness of the first adhesive layer 161 may be 15 μm to 25 μm. When the thickness of the first adhesive layer 161 satisfies the above range, the first adhesive layer 161 may have a coating property at a level at which manufacturing of the display device 100 is easy, and the display panel 130 may be prevented from being peeled off by the stress applied to the display panel 130 in the bending area BA, and bonding with other adhesive layers may be easy.

The second adhesive layer 162 may be disposed between the display panel 130 and the back plate 140 to attach the display panel 130 and the back plate 140. The second adhesive layer 162 is disposed to cover both the upper surface and the side portion of the back plate 140. Accordingly, the second adhesive layer 162 may protect and fix the side portion of the back plate 140. In this case, the second adhesive layer 162 may be in contact with the curved portion 112 of the cover glass 110 in the bending area BA or with the black matrix BM disposed inside the curved portion 112. Further, the second adhesive layer 162 may be in contact with the third adhesive layer 163 positioned below the second adhesive layer 162 and the first adhesive layer 161 positioned above the second adhesive layer 162 in the bending area BA. In this case, the thickness of the second adhesive layer 162 may be 15 μm to 45 μm. When the thickness of the second adhesive layer 162 satisfies the above range, the second adhesive layer 162 may have a coating property at a level at which manufacturing of the display device 100 is easy, and the display panel 130 may be prevented from being peeled off by the stress applied to the display panel 130 in the non-display area, and the second adhesive layer may be easily bonded to another adhesive layer.

The third adhesive layer 163 is disposed between the back plate 140 and the metal plate 150 to attach the back plate 140 and the metal plate 150. The third adhesive layer 163 may be disposed to cover the upper surface and the side portion of the metal plate 150. In this case, referring to FIG. 2, when the side portion of the metal plate 150 has a structure extending so as to be in contact with the curved portion 112 of the cover glass 110, the third adhesive layer 163 may be disposed so as to be in contact only with the upper surface of the metal plate 150 and not in contact with the side portion of the metal plate 150. The third adhesive layer 163 may be in contact with the curved portion 112 of the cover glass 110 in the bending area BA or with the black matrix BM disposed inside the curved portion 112. Further, the third adhesive layer 163 may be in contact with the second adhesive layer 162 positioned above the third adhesive layer 163 in the bending area BA. In this case, the thickness of the third adhesive layer 163 may be 15 μm to 30 μm. When the thickness of the third adhesive layer 163 satisfies the above range, the third adhesive layer 163 may have a coating property at a level that facilitates manufacturing the display device 100, and may prevent the opening pattern formed in the metal plate 150 in the bending area BA from being visually recognized on the front surface of the display device 100.

The fourth adhesive layer 164 may be disposed between the cover glass 110 and the polarizing film 120 to attach the cover glass 110 and the polarizing film 120. The fourth adhesive layer 164 is disposed to cover both the upper surface and the side portion of the polarizing film 120. Accordingly, the fourth adhesive layer 164 may protect and fix the side portion of the polarizing film 120. In this case, the fourth adhesive layer 164 may be in contact with the front portion 111 of the cover glass 110 in the non-bending area NBA and may be in contact with the curved portion 112 of the cover glass 110 in the bending area BA or with the black matrix BM disposed inside the curved portion 112. Further, the fourth adhesive layer 164 may be in contact with the first adhesive layer 161 positioned below the fourth adhesive layer 164 in the bending area BA. The thickness of the fourth adhesive layer 164 may be 45 μm to 100 μm. When the thickness of the fourth adhesive layer 164 satisfies the above range, the step formed by the black matrix BM may be covered to solve the problem of generating air bubbles in the step, and bonding with other adhesive layers may be facilitated. In the meantime, even though in FIG. 2, it is illustrated that the polarizing film 120 is disposed on the display panel 130, when the polarizing film 120 is excluded or disposed at a different position, the fourth adhesive layer 164 may be omitted.

The adhesive layer 160 may be integrally formed with the first adhesive layer 161, the second adhesive layer 162, the third adhesive layer 163, and the fourth adhesive layer 164 made of the same material and the same composition. Referring to FIG. 2, the adhesive layer 160 may be arbitrarily distinguished by a first adhesive layer 161, a second adhesive layer 162, a third adhesive layer 163, and a fourth adhesive layer 164 that are stacked between the components. However, the first adhesive layer 161, the second adhesive layer 162, the third adhesive layer 163, and the fourth adhesive layer 164 may have one integrated structure made of the same material. Accordingly, the adhesive layer 160 may be filled in the space surrounded by the cover glass 110 and the metal plate 150.

Specifically, the adhesive layer 160 may be formed of a curable adhesive. The curable adhesive may be made of a photocurable material or a thermosetting material. For example, the photocurable material may be formed using an ultraviolet (UV) curable resin, but is not limited thereto. The thermosetting material may be one compound selected from the group consisting of an epoxy-based, urethane-based, ester-based, and polyimide-based resin, or a mixture or copolymer of two or more, but is not limited thereto. The curable adhesive may have a viscosity of 1×10² Pa·s to 1×10⁶ Pa·s (25° C.), and a storage modulus before curing may be 1×10⁴ Pa to 1×10⁶ Pa. When the viscosity and storage modulus of the curable pressure-sensitive adhesive satisfy the above range, integration between the adhesive layers is facilitated through the flowability of the pressure-sensitive adhesive when the adhesive layer is formed, and a space enclosed by the cover glass 110 and the metal plate 150 is filled to easily cover the side surface of each component.

As described above, the first adhesive layer 161, the second adhesive layer 162, the third adhesive layer 163, and the fourth adhesive layer 164 may all be formed of the same curable adhesive. Accordingly, the crosslinking density may be partially different in the adhesive layer according to the degree of light or heat irradiation. In this case, the storage modulus of the adhesive layer 160 may be 1×10⁵ Pa to 1×10⁹ Pa. When the storage modulus of the adhesive layer 160 satisfies the above range, an adhesive force between the components may be secured, and a problem in that peeling, wrinkles, or bubbles are generated by a repulsive force which is to be restored to a shape before the components are bent in the bending area BA may be solved.

Hereinafter, a method of manufacturing a display device according to one or more embodiments of the present disclosure will be described.

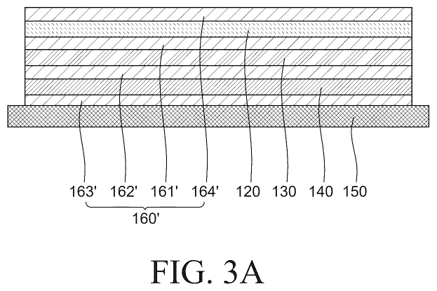

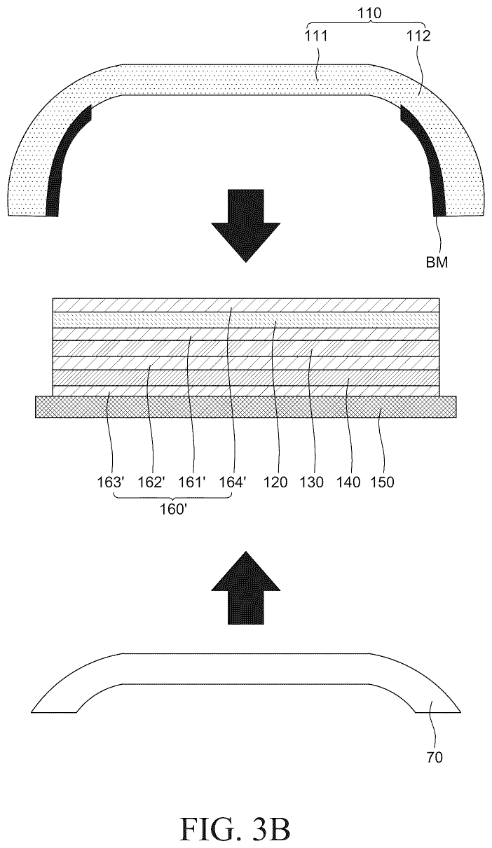

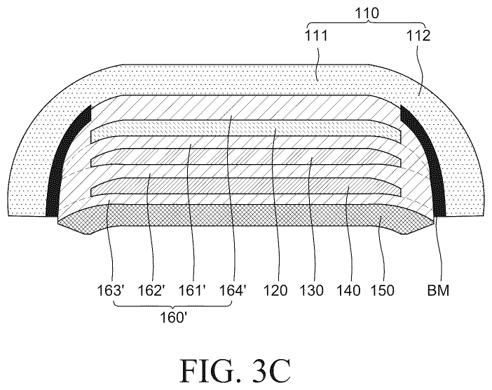

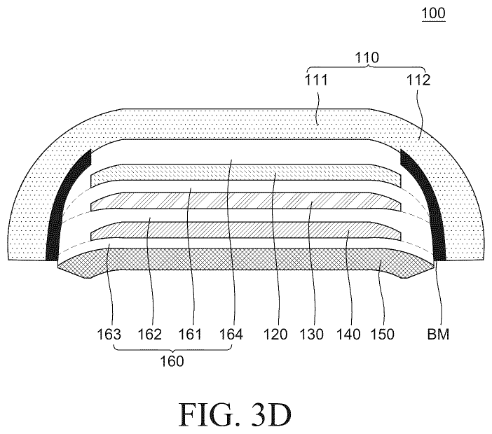

FIGS. 3A to 3D are schematic cross-sectional views for explaining a method of manufacturing the display device 100 according to one or more embodiments of the present disclosure.

First, referring to FIG. 3A, the back plate 140, the display panel 130, and the polarizing film 120 are sequentially stacked on the metal plate 150. At this time, an adhesive 160′ including a first adhesive 161′, a second adhesive 162′, a third adhesive 163′ and a fourth adhesive 164′ may be disposed, that is, the third adhesive 163′ is disposed between the metal plate 150 and the back plate 140, the second adhesive 162′ before hardening is disposed between the back plate 140 and the display panel 130, the first adhesive 161′ is disposed between the display panel 130 and the polarizing film 120, and the fourth adhesive 164′ is disposed on the polarizing film 120. The first adhesive 161′, the second adhesive 162′, the third adhesive 163′, and the fourth adhesive 164′ are curable adhesives and are applied or laminated on each component in a state prior to curing. In this case, the first adhesive 161′, the second adhesive 162′, the third adhesive 163′, and the fourth adhesive 164′ may be formed of a photocurable material or a thermosetting material. For example, the photocurable material may be formed using an ultraviolet (ultra Violet) curable resin, but is not limited thereto. The thermosetting material may be one compound selected from the group consisting of an epoxy-based, urethane-based, ester-based, and polyimide-based resin, or a mixture or copolymer of two or more, but is not limited thereto. The curable adhesive may have a viscosity of 1×10² Pa·s to 1×10⁶ Pa·s (25° C.), and a storage modulus before curing may be 1×10⁴ Pa to 1×10⁶ Pa.

Next, referring to FIG. 3B, the cover glass 110 is placed on the upper portion and the jig 70 is placed on the lower portion of the laminate manufactured in FIG. 3A, and then pressure is applied from the upper portion and/or the lower portion to bond the laminate manufactured in FIG. 3A inside the cover glass 110.

Next, referring to FIG. 3C, the first adhesive 161′, the second adhesive 162′, the third adhesive 163′, and the fourth adhesive 164′ bonded to the inside of the cover glass 110 are extended to the outside of each component by pressure to cover a side portion of each component or come into contact with the inside of the curved portion 112 of the cover glass 110. Since the first adhesive 161′, the second adhesive 162′, the third adhesive 163′, and the fourth adhesive 164′ are pre-curing steps, their viscosity is low and flowability is high so that the side portions of the polarizing film 120, the display panel 130, and the back plate 140 may be covered by the pressure during the bonding process and the space surrounded by the cover glass 110 and the metal plate 150 may be completely filled. Further, the fourth adhesive 164′ disposed on the polarizing film 120 may cover the side portion of the black matrix BM to fill a step formed on the side portion of the black matrix BM.

Next, referring to FIG. 3D, light or heat is irradiated to the first adhesive 161′, the second adhesive 162′, the third adhesive 163′, and the fourth adhesive 164′ to cure the first adhesive 161′, the second adhesive 162′, the third adhesive 163′, and the fourth adhesive 164′. In this case, as the first adhesive 161′, the second adhesive 162′, the third adhesive 163′, and the fourth adhesive 164′, which are stacked independently of each other, are cured, a boundary is not formed between the respective adhesives, so that an integrated adhesive layer may be formed. Accordingly, the cured first adhesive layer 161, the second adhesive layer 162, the third adhesive layer 163, and the fourth adhesive layer 164 are connected to each other to form an integrated adhesive layer and surround the upper, lower and side portions of the display panel 130, the polarizing film 120, and the back plate 140. Accordingly, the adhesive layer 160 may attach and fix the display panel 130, the polarizing film 120, and the back plate 140 to the cover glass 110 and the metal plate 150. Further, the adhesive layer 160 may protect side surfaces of the display panel 130, the polarizing film 120, and the back plate 140.

The display device 100 according to one or more embodiments of the present disclosure includes a cover glass 110 having a four-sided bending structure including a curved portion 112 in which all edges are bent. At this time, other components disposed under the cover glass 110 have a structure in which an edge is bent corresponding to the curved portion 112. At this time, when a conventional pressure-sensitive adhesive PSA is used to adhere components such as the back plate 140 or the display panel 130 disposed under the cover glass 110, sufficient adhesive strength may be ensured between the components stacked in the upper and lower portions. However, in the bending area BA corresponding to the curved portion 112 of the cover glass 110, there is a problem in that the adhesive strength is insufficient or bubbles or foreign substances are generated. Specifically, the pressure sensitive adhesive may not cover the components in the bending area BA in which the components have a curvature due to the nature of the material, or may not fill between the components, so that the adhesive strength is significantly lowered compared to the non-bending area NBA, which may degrade the durability of the display device 100. In addition, the back plate 140 or the display panel 130 has a greater bending stress than the cover glass 110 and has a large repulsive force to be restored to a shape before being bent, so that there may be a problem in that the separation between the components in the bending area BA or the adhesive strength decreases. Therefore, the adhesive force of the adhesive layer in the bending area BA may decrease, or the adhesive layer may not sufficiently cover the curved portion 112 of the cover glass 110, such that bubbles may occur in a portion of the adhesive layer portion in the bending area BA or wrinkles may occur.

In one or more embodiments of the present disclosure, the adhesive layer 160 covers each component corresponding to the curved portion 112 and fills the lower portion of the cover glass 110 to improve adhesion and durability. Specifically, the display device 100 according to one or more embodiments of the present disclosure forms the adhesive layer 160 having an integrated structure capable of simultaneously covering not only upper and lower surfaces of all components disposed under the cover glass 110 but also side portions. The adhesive layer 160 is formed using a curable adhesive to fill a space surrounded by the cover glass 110 and the metal plate 150 to easily cover the side surfaces of each component, thereby attaching and fixing the components. At this time, the adhesive layer 160 in the display device 100 according to one or more embodiments of the present disclosure maintains the convenience in the process while improving the adhesive strength in the curved portion 112 of the cover glass 110, thereby solving the problem of peeling, wrinkles, or air bubbles generated by the repulsive force that is to be restored to the shape before the component is bent. In addition, compared with the case of using a conventional pressure-sensitive adhesive, the adhesive layer covers the side surface of the black matrix BM, thereby solving the problem of generating air bubbles due to the step formed by the black matrix BM.

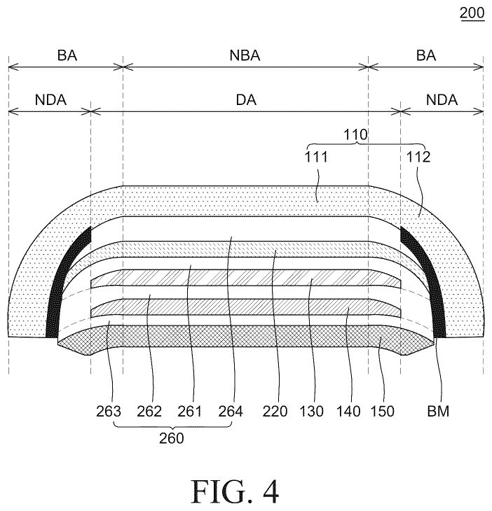

FIG. 4 is a schematic cross-sectional view of a display device according to one or more other embodiments of the present disclosure. A display device 200 illustrated in FIG. 4 is substantially identical in configuration to the display device 100 illustrated in FIGS. 1 and 3, except for a polarizing film 220 and an adhesive layer 260. Therefore, repeated descriptions of the identical components will be omitted.

The polarizing film 220 is disposed between the cover glass 110 and the display panel 130. In this case, the polarizing film 220 may have a width greater than that of the display panel 130. Referring to FIG. 4, the polarizing film 220 may have a greater width than the display panel 130 so as to be more adjacent to the cover glass 110 in the bending area BA compared to the display panel 130. Accordingly, the polarizing film 220 may extend to overlap a part of the non-display area NDA. Further, the polarizing film 220 may be disposed to be in contact with an inner surface of the curved portion 112 of the cover glass 110.

In the display device 200 according to one or more other embodiments of the present disclosure, a screen of the display panel 130 may be recognized through the curved portion 112 of the cover glass 110 disposed in the bending area BA and positioned in the bending area BA. Accordingly, by extending the polarizing film 220 to be in contact with the curved portion 112 of the cover glass 110, it is possible to block the reflection of light from the side portion of the display device 200.

Hereinafter, a method of manufacturing a display device according to one or more other embodiments of the present disclosure will be described.

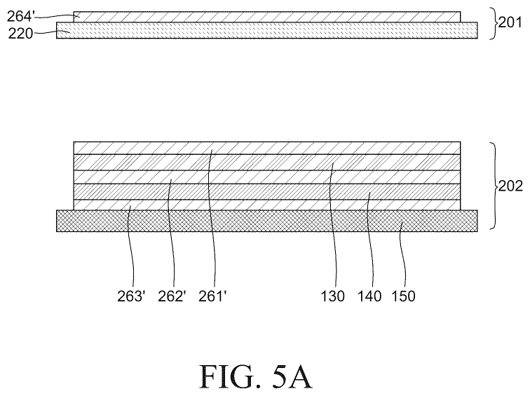

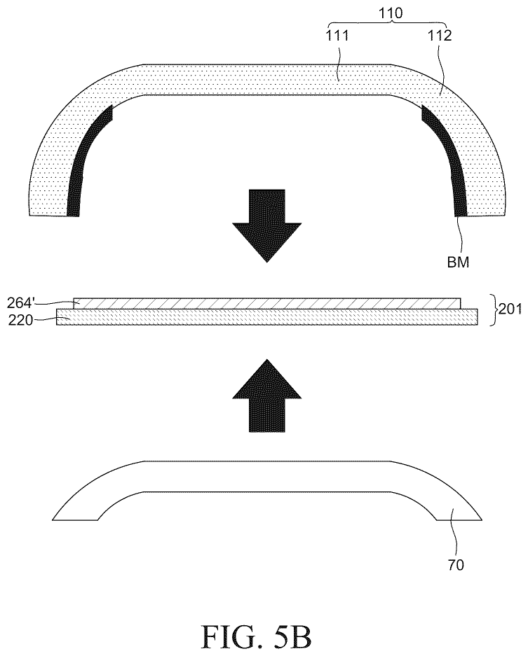

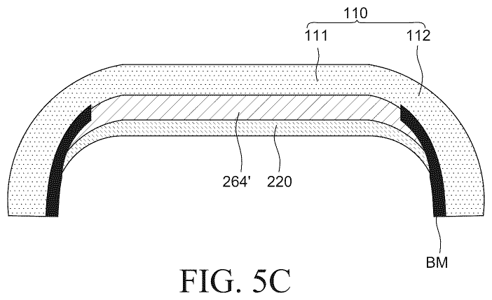

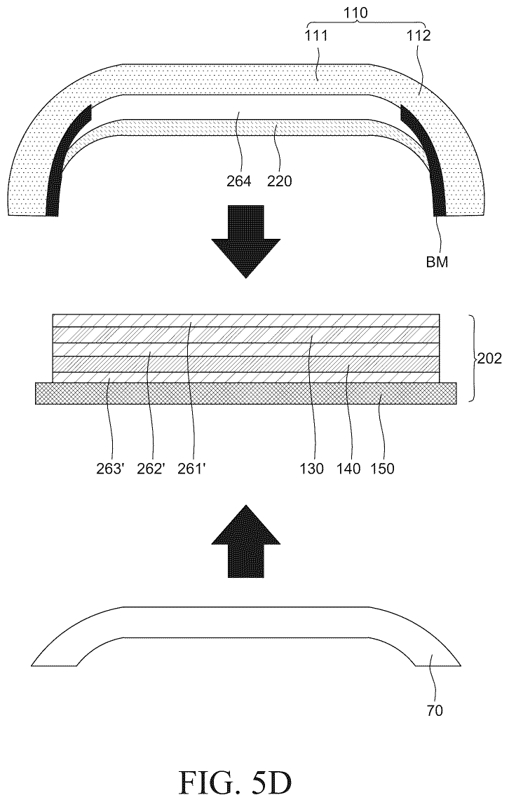

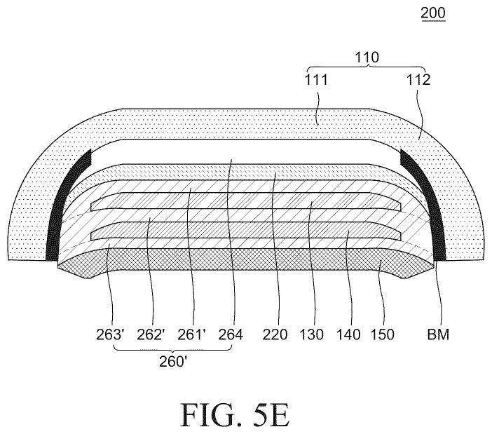

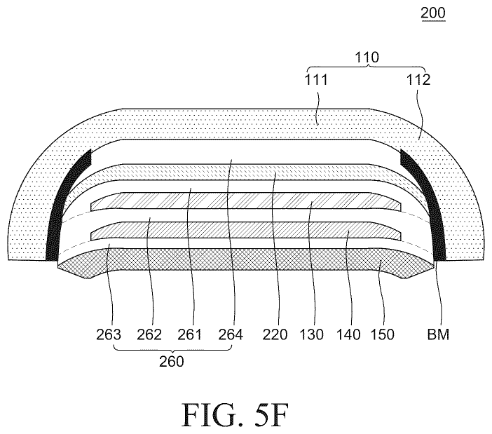

FIGS. 5A to 5F are schematic cross-sectional views for explaining a method of manufacturing the display device 100 according to one or more other embodiments of the present disclosure.

First, referring to FIG. 5A, a first laminate 201 in which a fourth adhesive 264′ is laminated on a polarizing film 220 and a second laminate 202 in which a third adhesive 263′, a back plate 140, a second adhesive 262′, a display panel 130, and a first adhesive 261′ are sequentially laminated on a metal plate 150 are manufactured. At this time, the width of the polarizing film 220 is larger than that of the display panel 130, and the width of the metal plate 150 is larger than that of the display panel 130 and the back plate 140. Meanwhile, the first adhesive 261′, the second adhesive 262′, the third adhesive 263′, and the fourth adhesive 264′ may be made of a light curable material or a thermally curable material. Therefore, redundant descriptions of the same as those of the first adhesive 261′, the third adhesive 263′, and the fourth adhesive 264′ are omitted in FIGS. 5B to 5F.

Next, referring to FIG. 5B, the cover glass 110 is placed on the upper portion and the jig 70 is placed on the lower portion of the first laminate 201 manufactured in FIG. 5A, and then pressure is applied from the upper portion and/or the lower portion to bond the first laminate 201 manufactured in FIG. 5A to the inside of the cover glass 110.

Next, referring to FIG. 5C, the polarizing film 220 is disposed to be in contact with the inside of the curved portion 112 of the cover glass 110. Further, the fourth adhesive 264′ bonded to the inside of the cover glass 110 extends outward by the pressure to be in contact with the inside of the curved portion 112 of the cover glass 110. The fourth adhesive 264′ may completely fill the space caused by the polarizing film 220 and the cover glass 110 through the bonding process. In particular, the fourth adhesive 264′ covers a side portion of the black matrix BM to fill a step formed on the side portion of the black matrix BM. Thereafter, light or heat is irradiated to the fourth adhesive 264′ to cure the fourth adhesive 264′.

Next, referring to FIG. 5D, the cover glass 110 to which the polarizing film 220 is bonded is positioned on the second laminate 202 manufactured in FIG. 5A, the jig 70 is positioned below the second laminate 202, and then pressure is applied from the upper portion and/or the lower portion to bond the second laminate 202 to the inside of the cover glass 110.

Next, referring to FIG. 5E, the first adhesive 261′, the second adhesive 262′, and the third adhesive 263′ bonded inside the cover glass 110 are expanded to the outside of each component by pressure to cover the side portions of each component or to be in contact with the inside of the curved portion 112 of the cover glass 110. Since the first adhesive 261′, the second adhesive 262′, and the third adhesive 263′ are in the pre-curing stage, the viscosity is low and the flowability is high, so that the side portions of the display panel 130 and the back plate 140 are covered by pressure during the bonding process, and the space surrounded by the cover glass 110 and the metal plate 150 may be completely filled.

Next, referring to FIG. 5F, light or heat is irradiated to the first adhesive 261′, the second adhesive 262′, and the third adhesive 263′ to cure the first adhesive 261′, the second adhesive 262′, and the third adhesive 263′. In this case, the first adhesive 261′, the second adhesive 262′, and the third adhesive 263′ which are stacked independently of each other are cured to be connected and integrated without forming a boundary between the adhesive agents. Accordingly, the cured first adhesive layer 261, the second adhesive layer 262, and the third adhesive layer 263 may be connected to each other to form an integrated adhesive layer 260 and surround the upper and lower surfaces and the side portions of the display panel 130 and the back plate 140. Accordingly, the adhesive layer 260 may attach and fix the display panel 130, the polarizing film 220, and the back plate 140 to the cover glass 110 and the metal plate 150. Further, the adhesive layer 260 may protect side surfaces of the display panel 130, the polarizing film 220, and the back plate 140.

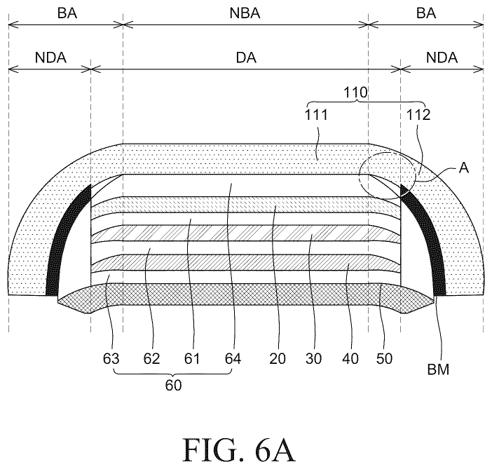

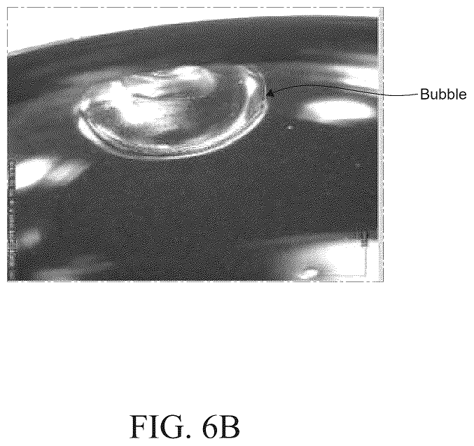

Hereinafter, an effect of the display device according to one or more embodiments of the present disclosure will be described with reference to FIGS. 6A and 6B together.

FIG. 6A is a schematic cross-sectional view of a display device according to a comparative example. FIG. 6B is an image obtained by photographing area A of FIG. 6A in a plane direction. The display device illustrated in FIG. 6A has substantially the same configuration as the display device 100 according to one or more embodiments of the present disclosure illustrated in FIG. 2 except for the adhesive layer 60. In the comparative example according to FIG. 6A, the display device includes the cover glass 110, the polarizing film 20, the display panel 30, the back plate 40, the metal plate 50 and the adhesive layer 60, and all the first adhesive layer 61, the second adhesive layer 62, the third adhesive layer 63, and the fourth adhesive layer 64 constituting the adhesive layer 60 are made of a pressure-sensitive adhesive. In the case of the pressure-sensitive adhesive, since the flowability of the adhesive is low, when the components including the display panel 130 are bonded to the inside of the cover glass 110, the side portions of the components are not covered or the curved portion 112 of the cover glass 110 is not filled. That is, the side portion of each adhesive layer is disposed to almost coincide with the side portions of each component. Accordingly, as shown in FIG. 6A, an empty space is formed inside the adhesive layer and the curved portion 112 of the cover glass 110, which may cause foreign substances and bubbles.

Meanwhile, as in the area A, the first adhesive layer 61 may not cover the step formed by the black matrix BM. Referring to FIG. 6B, the pressure sensitive adhesive fills the step difference It may be seen that air bubbles are generated on the side of the black matrix BM due to insufficient characteristics.

Hereinafter, the effects of the present disclosure will be described in more detail with reference to Embodiments and Comparative Examples. However, the following embodiments are for illustration of the present disclosure, and the scope of the present disclosure is not limited by the following embodiments.

### Embodiments 1 to 3

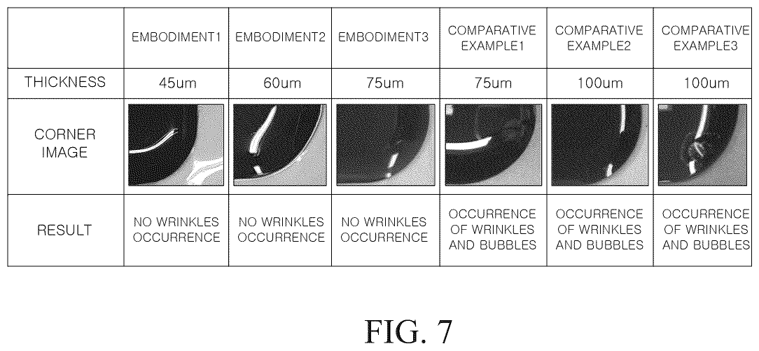

In the display device 100 illustrated in FIG. 2, the thickness of the cover glass 110 is 550 μm, the thickness of the polarizing film 220 is 75 μm, the thickness of the first adhesive layer 161 is 15 μm, the thickness of the display panel 130 is 40 μm, the thickness of the second adhesive layer 162 is 15 μm, the thickness of the back plate 140 is 100 μm, the thickness of the third adhesive layer 163 is 15 μm, and the thickness of the metal plate 150 is 50 μm, and the thickness of the fourth adhesive layer 164 disposed between the cover glass 110 and the polarizing film 220 is different as shown in FIG. 7 to prepare a sample. At this time, the first to fourth adhesive layers are formed using an epoxy-based thermosetting adhesive (modulus 10⁴ Pa before curing and 108 Pa after curing).

### Comparative Examples 1 to 3

Compared with Embodiments 1 to 3, a sample having the same structure was prepared except that the types of adhesives constituting the adhesive layer were different. At this time, in Comparative Examples 1 to 3, the first to fourth adhesive layers were formed using a pressure-sensitive adhesive.

### Experimental Example 1

Durability evaluation was performed for the manufactured Embodiments 1 to 3 and Comparative Examples 1 to 3. Specifically, the prepared sample was exposed for 100 hours in an environment of 65° C. in temperature and 90% humidity, and then the side portion of the black matrix BM disposed in the non-display area was observed to check whether wrinkles and bubbles were generated. Observation results are shown in FIG. 7.

Referring to FIG. 7, when an adhesive layer having a thickness of 45 μm to 75 μm is formed using a pressure-sensitive adhesive, it is confirmed that wrinkles and air bubbles are generated at corners. In contrast, when the adhesive layer is formed using the thermosetting adhesive as in Embodiments 1 to 3, it may be seen that wrinkles and air bubbles are not generated at the corners. Accordingly, in the display device according to the present disclosure, by using the thermosetting adhesive, the adhesive layer is formed to surround all the components inside the cover glass, thereby protecting the components of the display device and improving the durability at the corner.

### Experimental Example 2

In the prepared embodiment 1, while changing the thickness of the first adhesive layer, the coating properties of the first adhesive layer, the step coverage properties of the black matrix in the bending area of the display device, and adhesion properties were evaluated. The thickness of the first adhesive layer and the result of the properties are shown in Table 1 below. Coating properties were evaluated by whether the coating spreadability and thickness were uniform when the first adhesive layer was applied to the panel substrate, followed by a curing process, and then covered with a film. The step coverage properties were evaluated by whether air bubbles were generated between the first adhesive layer and the step formed on the cover glass printed with the black matrix. The adhesive properties were evaluated by attaching the cover glass, lower component, and adhesive layer using a jig and then checking for any defects in bonding.

TABLE 1

| | | | | STEP | |
|---|---|---|---|---|---|
| | | | COATING | COVERAGE | ADHESIVE |
| | Thickness | | PROPERTIES | PROPERTIES | PROPERTIES |
| Reference | 5 | μm | NG | — | — |
| example 1 | | | | | |
| Reference | 10 | μm | NG | — | — |
| example 2 | | | | | |
| Reference | 15 | μm | OK. | OK. | OK. |
| example 3 | | | | | |
| Reference | 25 | μm | OK. | OK | OK. |
| example 4 | | | | | |
| Reference | 30 | μm | OK. | OK | NG |
| example 5 | | | | | |
| Reference | 50 | μm | OK. | OK | NG |
| example 6 | | | | | |

Referring to Table 1, when the thickness of the first adhesive layer 161 disposed between the display panel 130 and the polarizing film 220 is 15 to 25 μm, the first adhesive layer 161 has a coating property to facilitate panel manufacturing and covers a step formed in the non-display area to prevent bubble formation. In addition, when the thickness of the first adhesive layer 161 exceeds 25 μm, it is confirmed that the stress applied to the display panel 130 located under the first adhesive layer 161 increases, and bonding with other adhesive layers is not performed in the bending area BA.

### Experimental Example 3

In the prepared embodiment 1, while changing the thickness of the second adhesive layer 162, the coating properties and durability of the black matrix BM in the bending area BA of the display device 100 were evaluated. The thickness of the second adhesive layer 162 and the evaluation result are shown in Table 2 below. Coating properties were evaluated by visually inspecting whether any attaining occurred when the second adhesive layer was applied to the back plate, cured, and covered with a film. The presence of wrinkles and peeling was visually confirmed whether wrinkles or peeling occurred on the back plate and the adhesive layer at the corner.

TABLE 2

| | COATING | Wrinkle and |
|---|---|---|
| Thickness | PROPERTIES | Peeling |

| | | | | |
|---|---|---|---|---|
| Reference | 5 | μm | NG | — |
| example 8 | | | | |
| Reference | 10 | μm | NG | — |
| example 9 | | | | |
| Reference | 15 | μm | OK | OK |
| example 10 | | | | |
| Reference | 30 | μm | OK | OK |
| example 11 | | | | |
| Reference | 45 | μm | OK | OK |
| example 12 | | | | |
| Reference | 60 | μm | OK | NG |
| example 13 | | | | |
| Reference | 75 | μm | OK | NG |
| example 14 | | | | |

Referring to Table 2, when the thickness of the second adhesive layer 162 disposed between the display panel 130 and the back plate 140 is 15 to 45 μm, the second adhesive layer 162 may have a coating property at a level that facilitates panel manufacturing. In addition, when the thickness of the first adhesive layer 161 exceeds 45 μm, it was confirmed that peeling or wrinkles occurred due to the repulsive force to restore the back plate 140 to the previous shape in the bending area BA.

### Experimental Example 4

In the prepared embodiment 1, while changing the thickness of the third adhesive layer 163, the coating properties and pattern visibility of the black matrix BM in the bending area BA of the display device 100 were evaluated. The thickness of the third adhesive layer 163 and the evaluation result are shown in Table 3 below. Coating properties were evaluated by visually inspecting whether any attaining occurred when the third adhesive layer was applied to the back plate, cured, and covered with a film. The presence of pattern visibility was evaluated visually whether the concave pattern (hundred μm) of the metal plate at the corner was visually recognized from the front.

TABLE 3

| | COATING | pattern |
|---|---|---|
| Thickness | PROPERTIES | visibility |

| | | | | |
|---|---|---|---|---|
| Reference | 5 | μm | NG | — |
| example 15 | | | | |
| Reference | 10 | μm | NG | — |
| example 16 | | | | |
| Reference | 15 | μm | OK | OK |
| example 17 | | | | |
| Reference | 30 | μm | OK | OK. |
| example 18 | | | | |
| Reference | 45 | μm | OK | NG |
| example 19 | | | | |
| Reference | 60 | μm | OK | NG |
| example 20 | | | | |

Referring to Table 3, when the thickness of the third adhesive layer 163 disposed between the back plate 140 and the metal plate 150 is 15 to 30 μm, the third adhesive layer 163 may have a coating property to facilitate panel manufacturing, and it may be seen that the opening pattern formed in the metal plate 150 corresponding to the bending area BA is not visible from the front surface of the display device 100.

The embodiments of the present disclosure can also be described as follows:

According to one or more embodiments of the present disclosure, there is provided a display device. The display device includes a non-bending area, a first bending area extending from a side portion of the non-bending area and a second bending area extending from a corner of the non-bending area and positioned between two first bending areas. The display device comprises a cover glass including a front portion corresponding to the non-bending area and a curved portion corresponding to the bending area and bent to have a curvature; a display panel disposed under the cover glass and including a first area corresponding to the non-bending area and a second area corresponding to the bending area; a metal plate supporting the display panel below the display panel; and an adhesive layer adhering the cover glass, the display panel, and the metal plate, and the adhesive layer covers a top surface, a bottom surface, and a side portion of the display panel and contacts the cover glass.

The adhesive layer may be in direct contact with the upper surface of the metal plate and the inner surface of the cover glass.

The adhesive layer may fill all spaces surrounded by the cover glass and the metal plate.

The display device may further comprise a black matrix disposed inside the curved portion of the cover glass, and the adhesive layer may cover side and lower surfaces of the black matrix.

The adhesive layer may be made of a curable adhesive.

The adhesive layer may have a storage modulus of 10⁵ Pa to 10⁹ Pa.

The adhesive layer may include a first adhesive layer disposed on a top surface of the display panel and a second adhesive layer disposed on a bottom surface of the display panel, and the first adhesive layer may cover a side portion of the display panel.

The first adhesive layer and the second adhesive layer may be made of the same material.

The display apparatus may further include a back plate disposed between the display panel and the metal plate, the adhesive layer may include a third adhesive layer disposed between the back plate and the metal plate, and the second adhesive layer may cover a side portion of the back plate.

The display apparatus may further include a polarizing film disposed between the display panel and the cover glass. The adhesive layer may further include a fourth adhesive layer disposed between the display panel and the polarizing film.

The fourth adhesive layer may cover a side portion of the polarizing film and may be connected to the first adhesive layer.

The side portion of the polarizing film may be disposed to protrude further outward than the side portion of the display panel.

The side portion of the polarizing film may be in contact with the curved portion of the cover glass, and the fourth adhesive layer may be filled between the cover glass and the polarizing film.

The first adhesive layer to the fourth adhesive layer may be connected to each other to be integrally formed.

The thickness of the first adhesive layer may be 15 μm to 25 μm, the thickness of the second adhesive layer may be 15 μm to 45 μm, the thickness of the third adhesive layer may be 15 μm to 30 μm, and the thickness of the fourth adhesive layer may be 45 μm to 100 μm.

Although the e embodiments of the present disclosure have been described in detail with reference to the accompanying drawings, the present disclosure is not limited thereto and may be embodied in various forms without departing from the technical concept of the present disclosure. Therefore, the embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device comprising a non-bending area, a first bending area extending from a side portion of the non-bending area, and a second bending area extending from a corner of the non-bending area and positioned between two first bending areas, the display device comprising:
a cover glass including a front portion corresponding to the non-bending area and a curved portion corresponding to a bending area, the curved portion bent to have a curvature;
a display panel disposed under the cover glass, the display panel including a first area corresponding to the non-bending area and a second area corresponding to the bending area;
a metal plate supporting the display panel below the display panel; and
an adhesive layer adhering the cover glass, the display panel and the metal plate,
wherein the adhesive layer covers a top surface of the display panel, a bottom surface of the display panel, and a side portion of the display panel, and
wherein the adhesive layer contacts the cover glass.

2. The display device of claim 1, wherein the adhesive layer directly contacts a top surface of the metal plate and an inner side surface of the cover glass.

3. The display device of claim 2, wherein the adhesive layer is filled in an entire space surrounded by the cover glass and the metal plate.

4. The display device of claim 1, further comprising:
a black matrix disposed inside the curved portion of the cover glass,
wherein the adhesive layer covers side surfaces of the black matrix and lower surfaces of the black matrix.

5. The display device of claim 1, wherein the adhesive layer includes a curable adhesive.

6. The display device of claim 1, wherein the adhesive layer has a storage modulus of 10⁵ Pa to 10⁹ Pa.

7. The display device of claim 1, wherein the adhesive layer includes a first adhesive layer disposed on a top surface of the display panel and a second adhesive layer disposed on a bottom surface of the display panel, and
wherein the first adhesive layer covers the side portion of the display panel.

8. The display device of claim 7, wherein the first adhesive layer and the second adhesive layer include a same material.

9. The display device of claim 7, further comprising:
a back plate disposed between the display panel and the metal plate,
wherein the adhesive layer further includes a third adhesive layer disposed between the back plate and the metal plate, and
wherein the second adhesive layer covers a side portion of the back plate.

10. The display device of claim 9, further comprising:
a polarizing film disposed between the display panel and the cover glass,
wherein the adhesive layer further includes a fourth adhesive layer disposed between the display panel and the polarizing film.

11. The display device of claim 10, wherein the fourth adhesive layer covers a side portion of the polarizing film, and wherein the fourth adhesive layer is connected to the first adhesive layer.

12. The display device of claim 10, wherein the side portion of the polarizing film is disposed to further protrude outward than the side portion of the display panel.

13. The display device of claim 12, wherein the side portion of the polarizing film is in contact with the curved portion of the cover glass, and
wherein the fourth adhesive layer is between the cover glass and the polarizing film.

14. The display device of claim 10, wherein the first adhesive layer, the second adhesive layer, the third adhesive layer and the fourth adhesive layer are connected to each other to be integrally formed.

15. The display device of claim 10, wherein a thickness of the first adhesive layer is 15 μm to 25 μm,
wherein a thickness of the second adhesive layer is 15 μm to 45 μm,
wherein a thickness of the third adhesive layer is 15 μm to 30 μm, and
wherein a thickness of the fourth adhesive layer is 45 μm to 100 μm.
